(19) United States
(12) Patent Application Publication
(10) Pub. No.: US 2014/0340864 A1
(43) Pub. Date: Nov. 20, 2014

(54) ELECTRONIC DEVICE AND ELECTROMAGNETIC INTERFERENCE SHIELDING STRUCTURE

(71) Applicant: Wistron Corporation, New Taipei City (TW)

(72) Inventors: Long-Hua Wu, New Taipei City (TW); Te-Hsiung Hsieh, New Taipei City (TW)

(21) Appl. No.: 13/927,126

(22) Filed: Jun. 26, 2013

(30) Foreign Application Priority Data
May 17, 2013 (CN) 201310184990.4

(51) Int. Cl. H05K 9/00

(52) U.S. Cl. CPC H05K 9/0081
USPC 361/818

(57) ABSTRACT

An electronic device of the invention includes a main chassis, an electronic module, a cage and an EMI shielding structure. The main chassis has an opening. The cage is assembled to the main chassis and covers the opening. The electronic module is disposed in the cage. The EMI shielding structure includes a conductive frame and at least one first conductive spring clip. The conductive frame is assembled to the cage and electrically connected to the electronic module. The first conductive spring clip is connected to the conductive frame and contacts the main chassis, in which an electromagnetic wave emitted by the electronic module sequentially passes through the conductive frame and the first conductive spring clip to be transmitted to the main chassis.

### CROSS-REFERENCE TO RELATED APPLICATION

This application claims the priority benefit of China application serial no. 201310184990.4, filed on May 17, 2013. The entirety of the above-mentioned patent application is hereby incorporated by reference herein and made a part of this specification.

### BACKGROUND OF THE INVENTION

1. Field of the Invention

The invention generally relates to an electronic device and an electromagnetic interference (EMI) shielding structure thereof, and more particularly, to an electronic device and an electromagnetic interference shielding structure with conductive spring clips.

2. Description of Related Art

With the advances in technology, the PC has been widely used in the working and living. The common PC currently includes desktop computer and notebook computer. Most of the PCs have connectors to connect an external expansion device or a data storage device.

In more details, a chassis of an electronic device such as a PC has an hole for exposing the connector and for the external device to plug in. At the time, the electromagnetic wave emitted from the connector of the electronic device or other electronic components may go outside through the hole on the chassis to cause EMI. Thus, how to use a simple conduction path to guide the electromagnetic wave emitted from the connector or other electronic components to the main chassis of the electronic device to achieve good EMI-shielding effect has become an important issue for designing an electronic device today.

### SUMMARY OF THE INVENTION

Accordingly, the invention is directed to an electronic device, wherein the EMI shielding structure has good EMI-shielding effect.

The invention is also directed to an EMI shielding structure with good EMI-shielding effect.

An electronic device of the invention includes a main chassis, an electronic module, a cage and an EMI shielding structure. The main chassis has an opening. The cage is assembled to the main chassis and covers the opening. The electronic module is disposed in the cage. The EMI shielding structure includes a conductive frame and at least one first conductive spring clip. The conductive frame is assembled to the cage and electrically connected to the electronic module. The first conductive spring clip is connected to the conductive frame and contacts the main chassis, in which an electromagnetic wave emitted by the electronic module sequentially passes through the conductive frame and the first conductive spring clip to be transmitted to the main chassis.

An EMI shielding structure of the invention is suitable for an electronic device, wherein the electronic device includes a main chassis, an electronic module and a cage, the cage is assembled to the main chassis and covers an opening of the main chassis, and the electronic module is disposed in the cage. The EMI shielding structure includes a conductive frame and at least one first conductive spring clip. The conductive frame is assembled to the cage and electrically connected to the electronic module. The first conductive spring clip is connected to the conductive frame and contacts the main chassis. An electromagnetic wave emitted by the electronic module sequentially passes through the conductive frame and the first conductive spring clip to be transmitted to the main chassis.

In an embodiment of the invention, the electronic module includes a circuit board and at least one connector, and the connector is disposed on the circuit board and electrically connected to the conductive frame.

In an embodiment of the invention, the cage has at least one hole and the hole exposes the connector.

In an embodiment of the invention, the EMI shielding structure further includes at least one second conductive spring clip, the second conductive spring clip is connected to the conductive frame and contacts the electronic module, the electromagnetic wave emitted by the electronic module sequentially passes through the second conductive spring clip, the conductive frame and the first conductive spring clip to be transmitted to the main chassis.

In an embodiment of the invention, the conductive frame, the first conductive spring clip and the second conductive spring clip are integrally formed.

In an embodiment of the invention, the main chassis has a bottom wall, the cage has a top wall, the top wall is located between the bottom wall and the EMI shielding structure and has at least one slot, and the first conductive spring clip goes through the slot to contact the bottom wall of the main chassis.

Based on the depiction above, the EMI shielding structure of the invention contacts the main chassis of the electronic device through the first conductive spring clip thereof, so that the conductive frame can be electrically connected to the main chassis without relying on the cage. Thus, after the electromagnetic wave emitted by the electronic module reaches the conductive frame, the electromagnetic wave can be directly transmitted to the main chassis through the first conductive spring clip, not via the cage for conducting. In this way, even the cage is made of a material with lower conductivity, a good conductive efficiency still can be kept between the EMI shielding structure and the main chassis, which ensures the electronic device to achieve the EMI-shielding effect.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a three-dimensional diagram of an electronic device according to an embodiment of the invention.

FIG. 2 is an exploded diagram of the electronic device of FIG. 1.

FIG. 3 is a partial cross-sectional diagram of the electronic device of FIG. 1.

FIG. 4 is a three-dimensional diagram of the cage and the EMI shielding structure in FIG. 2.

FIG. 5 is a diagram in another view of angle of the cage and the EMI shielding structure of FIG. 4.

### DESCRIPTION OF THE EMBODIMENTS

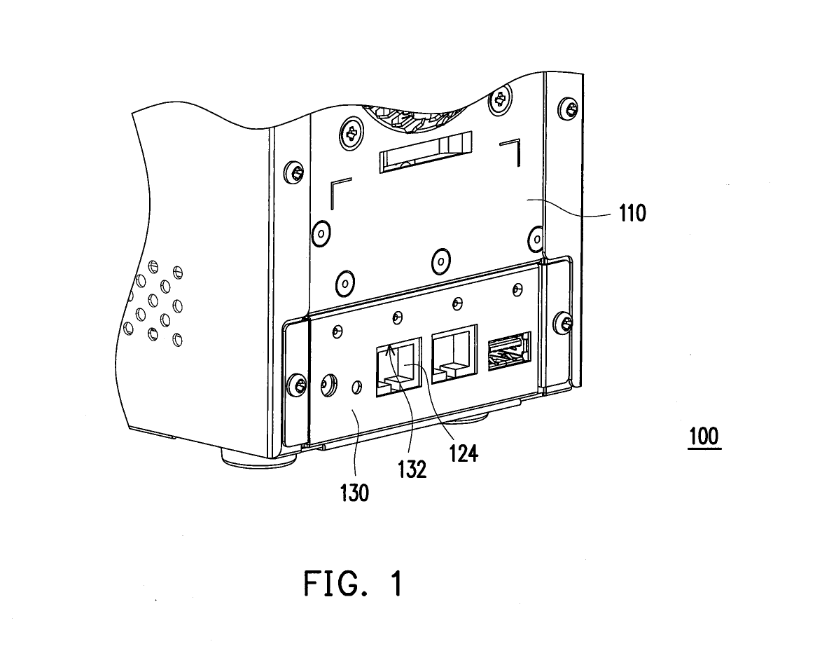

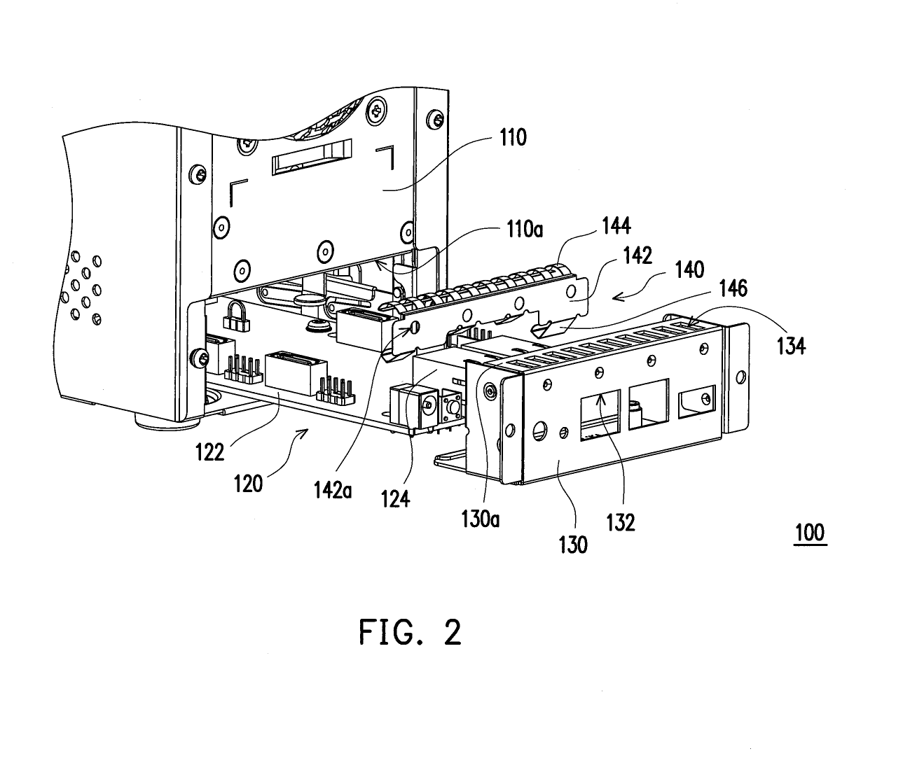

FIG. 1 is a three-dimensional diagram of an electronic device according to an embodiment of the invention and FIG. 2 is an exploded diagram of the electronic device of FIG. 1. Referring to FIGS. 1 and 2, an electronic device 100 of the embodiment includes a main chassis 110, an electronic module 120, a cage 130 and an EMI shielding structure 140. The main chassis 110 has an opening 110a, the cage 130 is assembled to the main chassis 110 and covers the opening 110a of the main chassis 110, and the cage 130 has at least one hole 132 (multiple ones are shown in FIG. 2). The electronic module 120 is disposed in the cage 130 and corresponding to the hole 132.

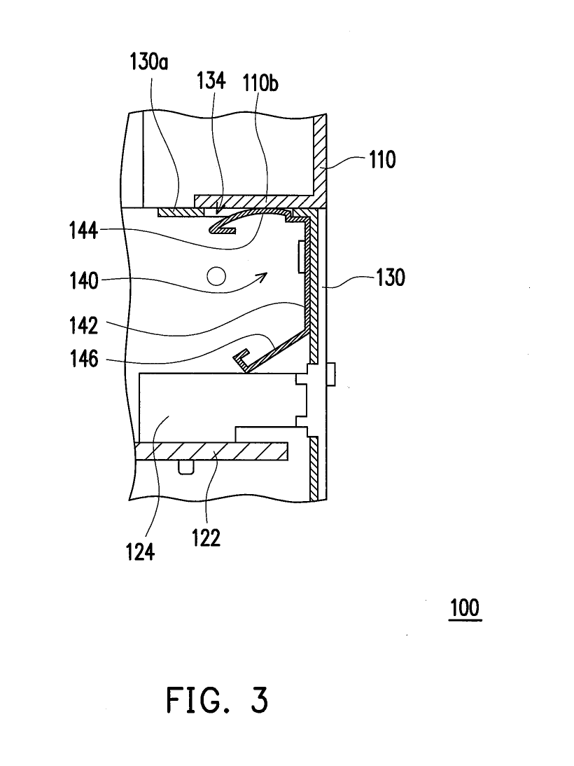

FIG. 3 is a partial cross-sectional diagram of the electronic device of FIG. 1. Referring to FIGS. 2 and 3, the EMI shielding structure 140 of the embodiment includes a conductive frame 142 and at least one connector 124 (multiple ones are shown in FIG. 2). The connector 124 is disposed on the circuit board 122 and electrically connected to the conductive frame 142. The hole 132 of the cage 130 is configured to expose the connector 124. The conductive frame 142 is assembled to the cage 130 and electrically connected to the main chassis 110, so that the electromagnetic wave emitted from the connector 124 is transmitted to the main chassis 110 via the conductive frame 142.

In more details, the EMI shielding structure 140 includes at least one first conductive spring clip 144 (multiple ones are shown in FIG. 2) and at least one second conductive spring clip 146 (multiple ones are shown in FIG. 2). The first conductive spring clip 144 is connected to the conductive frame 142 and contacts the main chassis 110 so that the conductive frame 142 is electrically connected to the main chassis 110. The second conductive spring clip 146 is connected to the conductive frame 142 and contacts the connector 124 of the electronic module 120 so that the conductive frame 142 is electrically connected to the connector 124. The electromagnetic wave emitted from the connector 124 of the electronic module 120 sequentially passes through the second conductive spring clip 146, the conductive frame 142 and the first conductive spring clip 144 to be transmitted to the main chassis 110.

Under the above-mentioned layout, since the EMI shielding structure 140 contacts the main chassis 110 of the electronic device 100 through the first conductive spring clip 144 thereof, the conductive frame 142 is able to electrically connect the main chassis 110 without relying on the cage 130. Thus, after the electromagnetic wave emitted from the connector 124 of the electronic module 120 reaches the conductive frame 142 via the second conductive spring clip 146, the electromagnetic wave can be directly transmitted to the main chassis 110 through the first conductive spring clip 144, not via the cage 130 for conducting. In this way, even the material of the cage 130 is one with lower conductivity (for example, galvanized steel plate), a good conductive efficiency between the EMI shielding structure 140 and the main chassis 110 is still kept, so that the electronic device 100 can reliably have EMI-shielding effect, and the electromagnetic wave emitted from the electronic module 120 can be avoided from reaching the outside via the hole 132 of the cage 130 or other gaps to cause the EMI.

In the embodiment, the material of the EMI shielding structure 140 is, for example, stainless steel with good conductivity so as to effectively transmit the electromagnetic wave come from the electronic module 120 to the main chassis 110. In other embodiments, the material of the EMI shielding structure 140 can be other appropriate materials, which the invention is not limited to.

The electronic device 100 in the embodiment is, for example, a host of a desktop computer, while in other embodiments, it can be an electronic device of other types, which the invention is not limited to. In addition to shield the electromagnetic wave come from the connector 124, the EMI shielding structure 140 in other embodiments can be used to shield the electromagnetic wave come from the electronic components of other types, which the invention is not limited to.

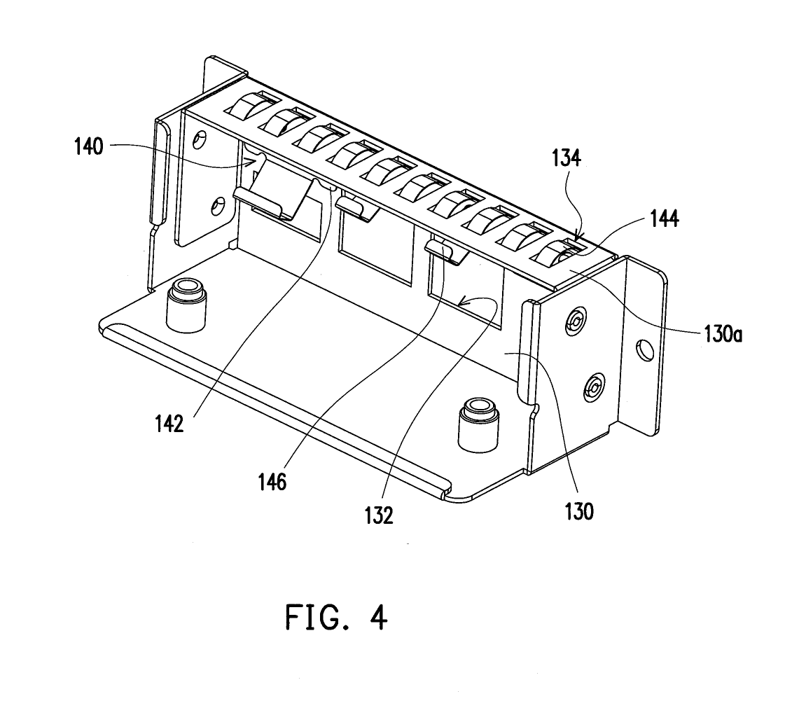

FIG. 4 is a three-dimensional diagram of the cage and the EMI shielding structure in FIG. 2. Referring to FIGS. 2-4, the main chassis 110 of the embodiment has a bottom wall 110b, the cage 130 has a top wall 130a, and the top wall 130a is located between the bottom wall 110b and the EMI shielding structure 140 and has at least one slot 134 (multiple ones are shown in FIGS. 2 and 4). The first conductive spring clip 144 of the EMI shielding structure 140 goes through the slot 134 of the top wall 130a of the cage 130 to contact the bottom wall 110b of the main chassis 110, which makes the EMI shielding structure 140 able to be electrically connected to the main chassis 110.

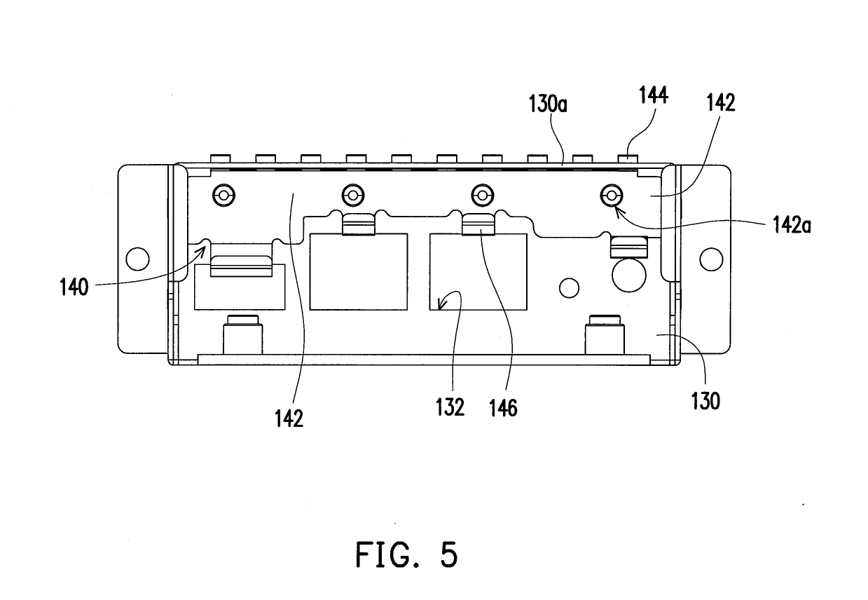

FIG. 5 is a diagram in another view of angle of the cage and the EMI shielding structure of FIG. 4. Referring to FIGS. 2 and 5, in the embodiment, the conductive frame 142 of the EMI shielding structure 140 has a plurality of riveting holes 142a and is riveted to the cage 130 through the riveting holes 142a. The conductive frame 142, the first conductive spring clip 144 and the second conductive spring clip 146 are, for example, integrally formed to simplify the fabrication and the assembling of the EMI shielding structure 140.

In summary, the EMI shielding structure of the invention contacts the main chassis of the electronic device through the first conductive spring clip thereof, so that the conductive frame can be electrically connected to the main chassis without relying on the cage. Thus, after the electromagnetic wave emitted by the connector of the electronic module reaches the conductive frame via the second conductive spring clip, the electromagnetic wave can be directly transmitted to the main chassis through the first conductive spring clip, not via the cage for conducting. In this way, even the cage is made of a material with lower conductivity, a good conductive efficiency still can be kept between the EMI shielding structure and the main chassis, so that the electronic device can reliably have EMI-shielding effect, and the electromagnetic wave emitted from the electronic module can be avoided from reaching the outside via the hole of the cage or other gaps cause the EMI.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. An electronic device, comprising:
a main chassis, having an opening;
a cage, assembled to the main chassis and covering the opening;
an electronic module, disposed in the cage; and
an electromagnetic interference shielding structure, comprising:
a conductive frame, assembled to the cage and electrically connected to the electronic module; and
at least one first conductive spring clip, connected to the conductive frame and contacting the main chassis, wherein an electromagnetic wave emitted by the electronic module sequentially passes through the conductive frame and the first conductive spring clip to be transmitted to the main chassis.

2. The electronic device as claimed in claim 1, wherein the electronic module comprises a circuit board and at least one connector, and the connector is disposed on the circuit board and electrically connected to the conductive frame.

3. The electronic device as claimed in claim 2, wherein the cage has at least one hole and the hole exposes the connector.

4. The electronic device as claimed in claim 1, wherein the electromagnetic interference shielding structure further comprises at least one second conductive spring clip, the second conductive spring clip is connected to the conductive frame and contacts the electronic module, the electromagnetic wave emitted by the electronic module sequentially passes through the second conductive spring clip, the conductive frame and the first conductive spring clip to be transmitted to the main chassis.

5. The electronic device as claimed in claim 4, wherein the conductive frame, the first conductive spring clip and the second conductive spring clip are integrally formed.

6. The electronic device as claimed in claim 1, wherein the main chassis has a bottom wall, the cage has a top wall, the top wall is located between the bottom wall and the electromagnetic interference shielding structure and has at least one slot, and the first conductive spring clip goes through the slot to contact the bottom wall of the main chassis.

7. An electromagnetic interference shielding structure, suitable for an electronic device, wherein the electronic device comprises a main chassis, an electronic module and a cage, the cage is assembled to the main chassis and covers an opening of the main chassis, the electronic module is disposed in the cage, and the electromagnetic interference shielding structure comprises:
a conductive frame, assembled to the cage and electrically connected to the electronic module; and
at least one first conductive spring clip, connected to the conductive frame and contacting the main chassis, wherein an electromagnetic wave emitted by the electronic module sequentially passes through the conductive frame and the first conductive spring clip to be transmitted to the main chassis.

8. The electromagnetic interference shielding structure as claimed in claim 7, wherein the electronic module comprises a circuit board and at least one connector, and the connector is disposed on the circuit board and electrically connected to the conductive frame.

9. The electromagnetic interference shielding structure as claimed in claim 8, wherein the cage has at least one hole and the hole exposes the connector.

10. The electromagnetic interference shielding structure as claimed in claim 7, further comprising at least one second conductive spring clip, wherein the second conductive spring clip is connected to the conductive frame and contacts the electronic module, the electromagnetic wave emitted by the electronic module sequentially passes through the second conductive spring clip, the conductive frame and the first conductive spring clip to be transmitted to the main chassis.

11. The electromagnetic interference shielding structure as claimed in claim 10, wherein the conductive frame, the first conductive spring clip and the second conductive spring clip are integrally formed.

12. The electromagnetic interference shielding structure as claimed in claim 7, wherein the main chassis has a bottom wall, the cage has a top wall, the top wall is located between the bottom wall and the electromagnetic interference shielding structure and has at least one slot, and the first conductive spring clip goes through the slot to contact the bottom wall of the main chassis.
